(19) United States
(12) Patent Application Publication
(10) Pub. No.: US 2025/0264812 A1
(43) Pub. Date: Aug. 21, 2025

(54) SYSTEMS AND METHODS WITH PHOTOLITHOGRAPHIC PATTERN DEFECT DETECTION

(71) Applicant: Samsung Electronics Co., Ltd., Suwon-si (KR)

(72) Inventors: Shashishekara Parampalli ADIGA, Bengaluru (IN); Changmin PARK, Hwaseong-si (KR); MyungSoo HWANG, Hwaseong-si (KR); Prashant Pandurang SHINDE, Bengaluru (IN); Priyadarshini Panemangalore PAI, Bengaluru (IN); Subramanya Mayya KOLAKE, Bengaluru (IN)

(73) Assignee: Samsung Electronics Co., Ltd., Suwon-si (KR)

(21) Appl. No.: 19/054,044

(22) Filed: Feb. 14, 2025

(30) Foreign Application Priority Data
Feb. 17, 2024 (IN) 202441011195

(51) Int. Cl. G03F 7/00

(52) U.S. Cl. CPC G03F 7/7065; G03F 7/70655; G03F 7/706837; G03F 7/706841

(57) ABSTRACT

Systems and methods with photolithographic pattern defect detection are provided. A method includes generating a first pixel density map including a first set of peaks and a first set of troughs respectively along a first direction in an image corresponding to a periodic pattern, generating a second pixel density map, for a localized region determined in the first pixel density map dependent on a determined position of a peak and a determined position of a trough, where the second pixel density map includes a second set of peaks and/or a second set of troughs along a second direction of the image that is perpendicular to the first direction, detecting one or more defects in the image by comparing a height/depth and width of a peak or trough of the second set of peaks or troughs with a height/depth threshold parameter and a width threshold parameter, respectively.

### CROSS-REFERENCE TO RELATED APPLICATIONS

This application claims the benefit under 35 USC § 119(a) of Indian Patent Application No. 202441011195 filed on Feb. 17, 2024, in the Indian Patent Office, the entire disclosure of which is incorporated herein by reference for all purposes.

### 1. FIELD

The following description relates to systems and methods with photolithographic pattern defect detection.

### 2. DESCRIPTION OF RELATED ART

Photolithography is a process used in semiconductor manufacturing to create patterns and features on silicon wafers that make up integrated circuits. Photolithography uses light and a photosensitive material to expose and etch desired patterns onto the wafer surface, which are then filled with electrical components or left exposed as required for the final product. The photolithography process is highly precise and is often used to create intricate patterns on very small wafers. Photolithographic patterns may typically include a series of parallel lines or an array of pillars or holes. Said periodic/repeated patterns can contain defects that are difficult to detect using existing techniques for detecting variations and defects in the photolithographic patterns.

FIG. 1 illustrates example defects in photolithographic patterns. Such defects typically include bridges between lines denoted by reference number 101, breaks in the line (i.e., gaps) denoted by reference number 103, two adjacent lines collapsing denoted by reference number 105, and missing or merged holes or pillars denoted by reference number 107.

A problem in current photolithography techniques is the detection of nanoscale defects in the photoresist patterns, and the problem is further accentuated as feature sizes shrink.

Artificial intelligence (AI)-powered defect detection methodologies have been used to detect defects from scanning electronic microscope (SEM) images of semiconductor products. However, AI-based defect detection techniques require a significant amount of training data in terms of training SEM images and labeling of defects therein, which is labor-intensive and difficult. Furthermore, AI-based defect detection techniques are additionally challenging due to typical noise in SEM images. Moreover, AI-based defect detection techniques may not detect small and subtle defects, which can adversely affect root-cause-analyses and yield improvement protocols.

Therefore, AI-based defect detection is challenging due to the small and subtle nature of defects in the advanced nodes, lack of training data, and very small anomaly population compared to the normal population. Furthermore, labeling (or annotating) a statistically significant number of defects for training data is a difficult task that leads to unreliable defect detection during real operational conditions.

FIG. 2 illustrates an example pixel density map 203 of an SEM image 201 of an example photolithographic pattern.

As illustrated, the pixel density map 203 of the SEM image 201 includes alternating (vertically illustrated) peaks (i.e., bright regions) and troughs (i.e., dark regions) that match the vertically illustrated pattern in the SEM image 201. Here, the pixel density map 203 may be understood to have been generated along the x-axis (i.e., horizontal direction) of the SEM image 201.

However, while differences between peaks and troughs in the pixel density map 203 may appear evident, and suggestive that a defect exists in the SEM image 201, the SEM image 201 is a fabricated or ideal (not real) SEM image.

Real world pixel density maps of real world SEM images will not be as uniform as the pixel density map 203 or as clearly suggestive of the existence of defects, as real world images typically have intensity deviations caused by reasons that may be inherent to the photolithographic process and/or noise due to imaging techniques. For example, FIG. 3 illustrates an example pixel density map 303 corresponding to a real world SEM image 301 of an example photolithographic pattern. In the pixel density map 303, there are two peaks and a central shallow region corresponding to each vertical line in the SEM image 301, and it is difficult to interpret from the pixel density map 303 whether a defect exists in the SEM image 303.

### SUMMARY

This Summary is provided to introduce a selection of concepts in a simplified form that are further described in the Detailed Description. This Summary is not intended to identify key features or essential features of the claimed subject matter, nor is it intended to be used as an aid in determining the scope of the claimed subject matter.

In one general aspect, a processor-implemented method includes generating a first pixel density map including a first set of peaks and a first set of troughs respectively along a first direction in a scanning electron microscope (SEM) image corresponding to a periodic pattern in the SEM image, where the first set of peaks are respective peaks in pixel density intensity in the first pixel density map and the first set of troughs are respective troughs in the pixel density intensity in first pixel density map, generating a second pixel density map, for a localized region determined in the first pixel density map dependent on a determined position of a peak in the first set of peaks and a determined position of a trough in the first set of troughs, where the second pixel density map includes a second set of peaks and/or a second set of troughs along a second direction of the SEM image that is perpendicular to the first direction, and where the second set of peaks are respective peaks in pixel density intensity in the second pixel density map and the second set of troughs are respective troughs in the pixel density intensity in the second pixel density map, detecting one or more first defects in the SEM image by comparing, for each of the second set of peaks, a corresponding height and width of a corresponding peak of the second set of peaks with a first height threshold parameter and a first width threshold parameter, respectively, when the second pixel density map includes the second set of peaks, and detecting one or more second defects in the SEM image by comparing, for each of the second set of troughs, a corresponding depth and width of a corresponding trough of the second set of troughs with a second depth threshold parameter and a second width threshold parameter, respectively, when the second pixel density map includes the second set of troughs.

The detecting of the one or more first defects may further include identifying a first set of defects, in the second pixel density map, with respect to the second set of peaks when at least one of the corresponding heights and widths of the corresponding peaks is a height and width that are respectively greater than the first height threshold parameter and the first width threshold parameter, and the detecting of the one or more second defects may further include identifying a second set of defects, in the second pixel density map, with respect to the second set of troughs when at least one of the corresponding depths and widths of the corresponding troughs is a depth and width that are lower than the second depth threshold parameter and greater than the second width threshold parameter, respectively.

The method may further include identifying, for each of a plurality of SEM images that include the SEM image, at least one periodic pattern that includes the periodic pattern.

The first direction may correspond to a direction either parallel or perpendicular to a direction of the at least one periodic pattern in the SEM image.

The method may further include correcting an orientation of the SEM image based on a periodicity of the periodic pattern, and, in the generating of the first pixel density map, the first set of peaks and the first set of troughs may be respectively generated along a first coordinate axis of the SEM image with corrected orientation.

The method may further include, for each peak in the first set of peaks, determining, along a second coordinate axis of the first pixel density map, a first pixel intensity value of a corresponding peak of the first set of peaks and first pixel intensity values of adjacent troughs, of the first set of troughs, to the corresponding peak, determining a point of half-maximum density value of the corresponding peak by using the first pixel intensity value of the corresponding peak and the first pixel intensity values of the adjacent troughs to the corresponding peak of the first set of peaks, determining two points for the corresponding peak of the first set of peaks on a first coordinate axis of the first pixel density map where a pixel density profile of the corresponding peak of the first set of peaks intersects with a line parallel to the first coordinate axis at the point of half-maximum density value of the corresponding peak of the first set of peaks, and determining a position of the corresponding peak of the first set of peaks using the first pixel intensity value of the corresponding peak of the first set of peaks and the determined two points for the corresponding peak of the first set of peaks.

A width of the localized region may correspond to a difference between the determined two points for the corresponding peak in the first set of peaks.

The method may further include, for each trough in the first set of troughs, determining, along a second coordinate axis of the first pixel density map, a first pixel intensity value of a corresponding trough of the first set of troughs and first pixel intensity values of adjacent peaks to the corresponding trough of the first set of troughs, determining a point of half-maximum density value of the corresponding trough of the first set of troughs by using the first pixel intensity value of the corresponding trough of the first set of troughs and the first pixel intensity values of the adjacent peaks to the corresponding trough of the first set of troughs, determining two points for the corresponding trough of the first set of troughs on a first coordinate axis of the first pixel density map where a density profile of the corresponding trough of the first set of troughs intersects with a line parallel to the first coordinate axis, at the point of half-maximum density value of the corresponding trough of the first set of troughs, and determining a position of the corresponding trough of the first set of troughs using the first pixel intensity value of the corresponding trough of the first set of troughs and the determined two points for the corresponding trough of the first set of troughs.

The method may further include determining the first height threshold parameter, the first width threshold parameter, the second depth threshold parameter, and the second width threshold parameter by optimizing, using a machine learning (ML) model, one or more initial threshold parameters associated with standard deviations of the corresponding heights and the corresponding widths of the corresponding peaks of the second set of peaks, and the corresponding depths and the corresponding widths of the corresponding troughs of the second set of troughs.

The optimizing may include obtaining a subset of a plurality of SEM images that include the SEM image, detecting a set of defects in the obtained subset of the plurality of SEM images based on the one or more initial threshold parameters, and optimizing, using the ML model, the one or more initial threshold parameters based on user feedback may include one or more incorrect defects in the set of defects and/or one or more missed defects in the set of defects.

In one general aspect, a computing system includes one or more processors, and a memory storing code, which when executed by the one or more processors configures the one or more processors to generate a first pixel density map including a first set of peaks and a first set of troughs respectively along a first direction in a scanning electron microscope (SEM) image corresponding to a periodic pattern in the SEM image, where the first set of peaks are respective peaks in pixel density intensity in the first pixel density map and the first set of troughs are respective troughs in the pixel density intensity in first pixel density map, generate a second pixel density map, for a localized region determined in the first pixel density map dependent on a determined position of a peak in the first set of peaks and a determined position of a trough in the first set of troughs, where the second pixel density map includes a second set of peaks and/or a second set of troughs along a second direction of the SEM image that is perpendicular to the first direction, and where the second set of peaks are respective peaks in pixel density intensity in the second pixel density map and the second set of troughs are respective troughs in the pixel density intensity in the second pixel density map, detect one or more first defects in the SEM image by comparing, for each of the second set of peaks, a corresponding height and width of a corresponding peak of the second set of peaks with a first height threshold parameter and a first width threshold parameter, respectively, when the second pixel density map includes the second set of peaks, and detect one or more second defects in the SEM image by comparing, for each of the second set of troughs, a corresponding depth and width of a corresponding trough of the second set of troughs with a second depth threshold parameter and a second width threshold parameter, respectively, when the second pixel density map includes the second set of troughs.

For the detecting of the one or more first defects, the code may configure the one or more processors to identify a first set of defects, in the second pixel density map, with respect to the second set of peaks when at least one of the corresponding heights and widths of the corresponding peaks is a height and width that are respectively greater than the first height threshold parameter and the first width threshold parameter, and, for the detecting of the one or more second defects, the code may configure the one or more processors to identify a second set of defects, in the second pixel density map, with respect to the second set of troughs when at least one of the corresponding depths and widths of the corresponding troughs is a depth and width that are lower than the second depth threshold parameter and greater than the second width threshold parameter, respectively.

The code may further configure the one or more processors to identify, for each of a plurality of SEM images that include the SEM image, at least one periodic pattern that includes the periodic pattern.

The first direction may correspond to a direction either parallel or perpendicular to the at least one periodic pattern in the SEM image.

The code may further configure the one or more processors to correct an orientation of the SEM image based on a periodicity of the periodic pattern, and, in the generating of the first pixel density map, the first set of peaks and the first set of troughs may be respectively generated along a first coordinate axis of the SEM image with corrected orientation.

The code may further configure the one or more processors to, for each peak in the first set of peaks, determine, along a second coordinate axis of the first pixel density map, a first pixel intensity value of a corresponding peak of the first set of peaks and first pixel intensity values of adjacent troughs, of the first set of troughs, to the corresponding peak, determine a point of half-maximum density value of the corresponding peak by using the first pixel intensity value of the corresponding peak and the first pixel intensity values of the adjacent troughs to the corresponding peak of the first set of peaks, determine two points for the corresponding peak of the first set of peaks on a first coordinate axis of the first pixel density map where a pixel density profile of the corresponding peak of the first set of peaks intersects with a line parallel to the first coordinate axis at the point of half-maximum density value of the corresponding peak of the first set of peaks, and determine a position of the corresponding peak of the first set of peaks using the first pixel intensity value of the corresponding peak of the first set of peaks and the determined two points for the corresponding peak of the first set of peaks.

A width of the localized region may correspond to a difference between the determined two points for the corresponding peak in the first set of peaks.

The code may further configure the one or more processors to, for each trough in the first set of troughs, determine, along a second coordinate axis of the first pixel density map, a first pixel intensity value of a corresponding trough of the first set of troughs and first pixel intensity values of adjacent peaks to the corresponding trough of the first set of troughs, determine a point of half-maximum density value of the corresponding trough of the first set of troughs by using the first pixel intensity value of the corresponding trough of the first set of troughs and the first pixel intensity values of the adjacent peaks to the corresponding trough of the first set of troughs, determine two points for the corresponding trough of the first set of troughs on a first coordinate axis of the first pixel density map where a density profile of the corresponding trough of the first set of troughs intersects with a line parallel to the first coordinate axis, at the point of half-maximum density value of the corresponding trough of the first set of troughs, and determine a position of the corresponding trough of the first set of troughs using the first pixel intensity value of the corresponding trough of the first set of troughs and the determined two points for the corresponding trough of the first set of troughs.

The code may further configure the one or more processors to determine the first height threshold parameter, the first width threshold parameter, the second depth threshold parameter, and the second width threshold parameter by optimizing, using a machine learning (ML) model, one or more initial threshold parameters associated with standard deviations of the corresponding heights and the corresponding widths of the corresponding peaks of the second set of peaks, and the corresponding depths and the corresponding widths of the corresponding troughs of the second set of troughs.

For the optimizing of the one or more initial threshold parameters, the code may configure the one or more processors to obtain a subset of a plurality of SEM images that include the SEM image, detect a set of defects in the obtained subset of the plurality of SEM images based on the one or more initial threshold parameters, and optimize, using the ML model, the one or more initial threshold parameters based on user feedback that may include one or more incorrect defects in the set of defects and/or one or more missed defects in the set of defects.

Other features and aspects will be apparent from the following detailed description, the drawings, and the claims.

### BRIEF DESCRIPTION OF THE DRAWINGS

FIG. 1 illustrates example defects in photolithographic patterns.

FIG. 2 illustrates an example pixel density map corresponding to an SEM image of an example photolithographic pattern.

FIG. 3 illustrates an example pixel density map corresponding to a real world SEM image of an example photolithographic pattern.

FIG. 4 illustrates an example computing system, according to one or more embodiments of the present disclosure.

FIG. 5 illustrates example defect detection operations, according to one or more embodiments of the present disclosure.

FIG. 6 is a flow diagram of example defect detection operations, according to one or more embodiments of the present disclosure.

FIG. 7 illustrates an example defect detection performed using an example SEM image, according to one or more embodiments of the present disclosure.

FIG. 8 illustrates a method of determining positions of peaks and troughs in an example pixel density map, according to one or more embodiments of the present disclosure.

FIG. 9 illustrates an example defect detection performed using an example second-pixel density map, according to one or more embodiments of the present disclosure.

FIG. 10 illustrates example sensitivities in defect detection with different threshold values, according to one or more embodiments of the present disclosure.

FIG. 11 illustrates a method for detecting one or more defects in a plurality of SEM images of example photolithographic patterns, according to one or more embodiments of the present disclosure.

FIG. 12 illustrates an example defect detection performed using an example SEM image with an example hole photolithographic pattern, according to one or more embodiment of the present disclosure.

Throughout the drawings and the detailed description, unless otherwise described or provided, the same drawing reference numerals may be understood to refer to the same or like elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences within and/or of operations described herein are merely examples, and are not limited to those set forth herein, but may be changed as will be apparent after an understanding of the disclosure of this application, except for sequences within and/or of operations necessarily occurring in a certain order. As another example, the sequences of and/or within operations may be performed in parallel, except for at least a portion of sequences of and/or within operations necessarily occurring in an order, e.g., a certain order. Also, descriptions of features that are known after an understanding of the disclosure of this application may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application. The use of the term “may” herein with respect to an example or embodiment (e.g., as to what an example or embodiment may include or implement) means that at least one example or embodiment exists where such a feature is included or implemented, while all examples are not limited thereto. The use of the terms “example” or “embodiment” herein have a same meaning (e.g., the phrasing “in one example” has a same meaning as “in one embodiment”, and “one or more examples” has a same meaning as “in one or more embodiments”).

Although terms such as “first,” “second,” and “third”, or A, B, (a), (b), and the like may be used herein to describe various members, components, regions, layers, or sections, these members, components, regions, layers, or sections are not to be limited by these terms. Each of these terminologies is not used to define an essence, order, or sequence of corresponding members, components, regions, layers, or sections, for example, but used merely to distinguish the corresponding members, components, regions, layers, or sections from other members, components, regions, layers, or sections. Thus, a first member, component, region, layer, or section referred to in the examples described herein may also be referred to as a second member, component, region, layer, or section without departing from the teachings of the examples.

The terminology used herein is for describing various examples only and is not to be used to limit the disclosure. The articles “a,” “an,” and “the” are intended to include the plural forms as well, unless the context clearly indicates otherwise. As non-limiting examples, terms “comprise” or “comprises,” “include” or “includes,” and “have” or “has” specify the presence of stated features, numbers, operations, members, elements, and/or combinations thereof, but do not preclude the presence or addition of one or more other features, numbers, operations, members, elements, and/or combinations thereof, or the alternate presence of an alternative stated features, numbers, operations, members, elements, and/or combinations thereof. Additionally, while one embodiment may set forth such terms “comprise” or “comprises,” “include” or “includes,” and “have” or “has” specify the presence of stated features, numbers, operations, members, elements, and/or combinations thereof, other embodiments may exist where one or more of the stated features, numbers, operations, members, elements, and/or combinations thereof are not present.

As used herein, the term “and/or” includes any one and any combination of any two or more of the associated listed items. The phrases “at least one of A, B, and C”, “at least one of A, B, or C”, and the like are intended to have disjunctive meanings (e.g., each phrase may include any one of the respective items alone, all of the items listed together, and all possible combinations thereof), and these phrases “at least one of A, B, and C”, “at least one of A, B, or C”, and the like also include examples where there may be one or more of each of A, B, and/or C (e.g., any combination of one or more of each of A, B, and C), unless the corresponding description and embodiment necessitates such listings (e.g., “at least one of A, B, and C”) to be interpreted to have a conjunctive meaning.

Unless otherwise defined, all terms, including technical and scientific terms, used herein have the same meaning as commonly understood by one of ordinary skill in the art to which this disclosure pertains and specifically in the context on an understanding of the disclosure of the present application. Terms, such as those defined in commonly used dictionaries, are to be interpreted as having a meaning that is consistent with their meaning in the context of the relevant art and specifically in the context of the disclosure of the present application, and are not to be interpreted in an idealized or overly formal sense unless expressly so defined herein.

Embodiments may be described and illustrated in terms of blocks that carry out a described operation. These blocks are physically implemented by analog or digital circuits such as logic gates, integrated circuits, microprocessors, microcontrollers, memory circuits, passive electronic components, active electronic components, optical components, hardwired circuits, or the like and as non-limiting examples, and may optionally be circuitry driven by code, such as firmware or program(s). The circuits may, for example, be embodied in one or more semiconductor chips, or on substrate supports such as printed circuit boards and the like. The circuits making up a block may be implemented by dedicated hardware, by a processor (e.g., one or more programmed microprocessors and associated circuitry), or by a combination of dedicated hardware to perform some operations of the block and a processor to perform other operations of the block. Each block of the embodiments may be physically separated into two or more interacting and discrete blocks without departing from the scope of the disclosure. Likewise, the blocks of the embodiments may be physically combined into more complex blocks without departing from the scope of the disclosure.

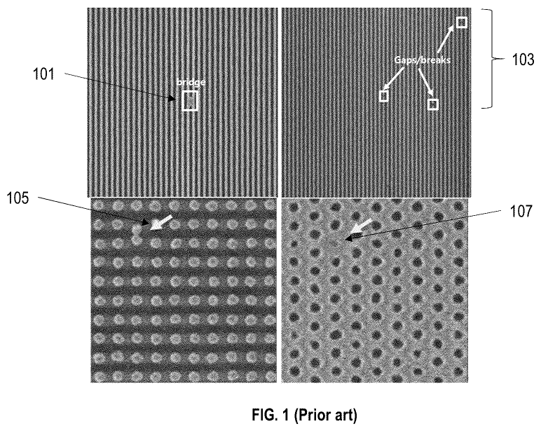

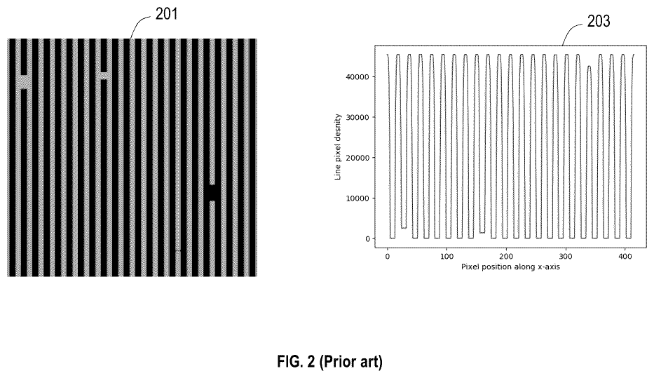

Further to the above explanation of FIGS. 1-3, it is found by the inventors that, with technology nodes diminishing in size, there is a growing need for high-precision defect detection techniques. To that effect, it is found that Artificial intelligence (AI)-powered defect detection methodologies may be used to optimize product yield and reduce manufacturing costs, since manual detection is both time-consuming and error-prone.

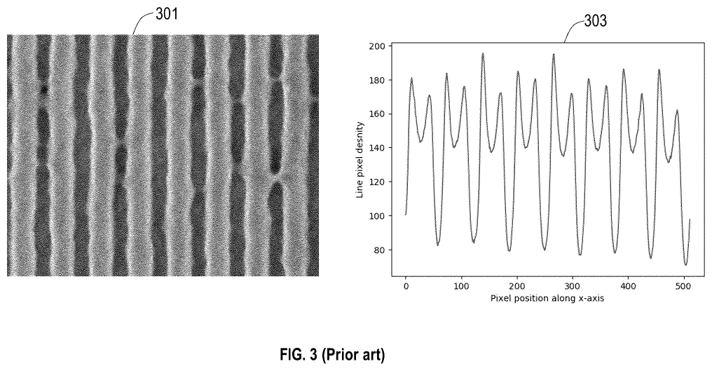

However, as demonstrated above with respect to FIG. 3, it is found that real SEM images of photolithographic patterns have largely varying pixel densities due to the stochastic nature of the photolithographic process and/or noise introduced due to the imaging technique. Consequently, it is found that previous methodologies for defect detection fail to determine the exact (or best) location of the lines or any other periodic pattern, which may be important for detecting defects in SEM images of photolithographic patterns. Moreover, it is found that previous methodologies are not adequate for detecting stochastic defects in photolithographic patterns, as such previous methodologies may only rely on detecting defects based on differences with respect to a reference image or only use predefined rules to identify defects based on hard-wired defect threshold values. Accordingly, the inventors have found there is a need to provide an improved method for detecting defects in photolithographic patterns.

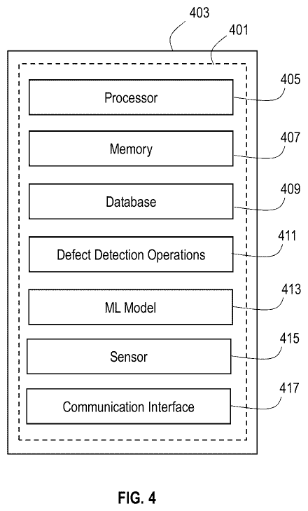

FIG. 4 illustrates an example computing system, according to one or more embodiments of the present disclosure.

Referring to FIG. 4, a computing system 403 may be configured to detect defects in a plurality of SEM images of photolithographic patterns. In an example, the computing system 403 may be implemented in a computing device 401. In an embodiment, the computing system 403 may be implemented in a distributed manner in more than one user device. In an example embodiment, the computing device 401 may include, but is not limited to, desktop computer/Laptop, tablet or any other mobile device using this app or a computing platform attached to a scanning electron microscope or other metrology device in fabrication line.

The computing system 403 includes a processor 405, a memory 407, and a database 409 coupled with each other. The computing system 403 may further include a sensor 415 (e.g., the scanning electron microscope or other metrology device), and a communication interface 417 (e.g., a bus or transceiver). For example, in one or more embodiments described herein, the computing system 403 may obtain one or more SEM images from the sensor 415 directly, using the communication interface 417, or as stored in the database 409 and/or memory 407, as non-limiting examples.

In an example, the processor 405 may include one or more processors 405, which may include a single processing element (i.e., processing or computing circuitry) or a number of processing elements (i.e., processing or computing circuitries). The processor 405 may be one or more microprocessors, microcomputers, microcontrollers, digital signal processors (DSPs), general purpose processors such as central processing units (CPUs), application processors (APs), or the like, graphic processing units (GPUs), visual processing units (VPUs), AI-dedicated processors such as neural processing units (NPUs), logical processors, virtual processors, state machines, logic circuitries, and/or any processing circuitries that manipulate signals based on operational instructions. The processor 405 may be configured to fetch data stored in memory 407 and store data to memory 407, and the processor 405 may be configured to fetch and execute computer-readable instructions stored in memory 407 to configure or cause the processor 405 to perform any one, any combination, or all operations described herein.

The memory 407 may include one or more memories 407, which may include any non-transitory computer-readable medium known in the art including, for example, volatile memory or Random Access Memory (RAM), such as static random access memory (SRAM) and dynamic random access memory (DRAM), and/or non-volatile memory, such as read-only memory (ROM), erasable programmable ROM, flash memories, hard disks, optical disks, and magnetic tapes.

At least one of a plurality of operations of the computing system 403 may be implemented through use of an AI model. An operation associated with AI may be performed using the memory 407, e.g., including such non-volatile memory and/or volatile memory, and the processor 405. For example, the computing system 403 may further include an ML model 413. As non-limiting examples, the ML model 413 may be stored in the memory 407 and executable by the processor 405. The illustrated ML model 413 may also represent a specialized AI processor configured to execute ML or other AI models, such as the NPU(s) and/or GPU(s).

The processor 405 may control the processing of input data in accordance with predefined operating rules stored in the non-volatile memory and/or the volatile memory and/or in accordance with the ML model 413 or other AI models (e.g., stored in memory 407). The processor 405 may be configured to perform pre-processing operation(s) on data (e.g., of a captured, received, or otherwise obtained image) to convert the data into a form predetermined appropriate for use as an input to the ML model 413. In an example where the illustrated ML model 413 also represents the specialized AI processor, the processor 405 may control the provision of information to the specialized AI processor, the initiation of operations of the specialized AI processor, and may perform operations based on results of the execution of the ML model 413 by the specialized AI processor. The predefined operating rules and the ML model 413 may be generated through machine training or learning (e.g., by the processor 405 and/or through a separate server/other computing device 401), for example. Herein, machine learning means that, by applying a machine learning technique to a plurality of learning or training data, a predefined operating rule or AI model of a desired characteristic or configured to perform a particular task is generated. The ML model 413 may represent one or more AI models.

As non-limiting examples, the AI model(s) described herein (e.g., including the ML Model 413) may include neural network(s), which may include a plurality of neural network layers. Each layer may have a plurality of weights (e.g., each having a weight value resulting from the machine learning) and may perform a particular layer operation based on an application of a plurality of weights against one or more inputs that respectively result from the calculations of one or more previous layers (which may also include a resultant calculation from the same layer or one or more subsequent layers). Examples of the neural networks may include, but are not limited to, convolutional neural network (CNN), deep neural network (DNN), recurrent neural network (RNN), restricted Boltzmann Machine (RBM), deep belief network (DBN), bidirectional recurrent deep neural network (BRDNN), generative adversarial networks (GAN), and deep Q-networks.

Examples of machine learning techniques include, but are not limited to, supervised learning, unsupervised learning, semi-supervised learning, or reinforcement learning as well understood in the art. In an example, the machine learning technique may include training a predetermined target device (for example, a robot, camera, or defect detection designated system or device (e.g., computing system 403 or computing device 401) using a plurality of learning data to cause, allow, or control the target device to make a determination or prediction.

The database 409 may include one or more database repositories for storing data, such as SEM images used for defect detection and/or used for threshold optimization by training of the ML model 413.

The computing system 403 may further include one or defect detection operations 411. In one or more embodiments, the defect detection operations 411 may include a set of instructions that may be executed to cause the device 401 to perform defect detection on (or dependent on) one or more SEM images of photolithographic patterns. The defect detection operations 411 may represent one or more respective defect detection operations that may be implemented by the processor 405, and/or software or other code that may be stored in memory 407 and executed by processor 405.

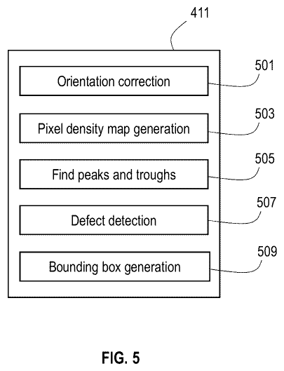

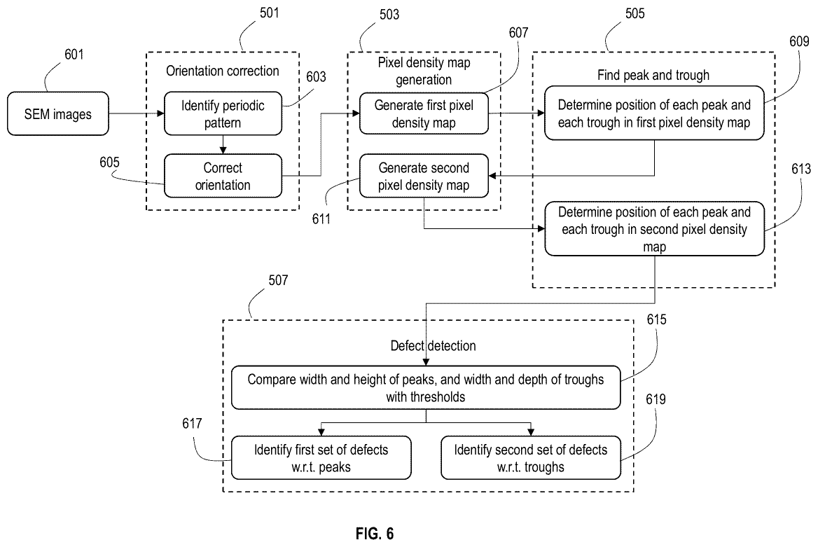

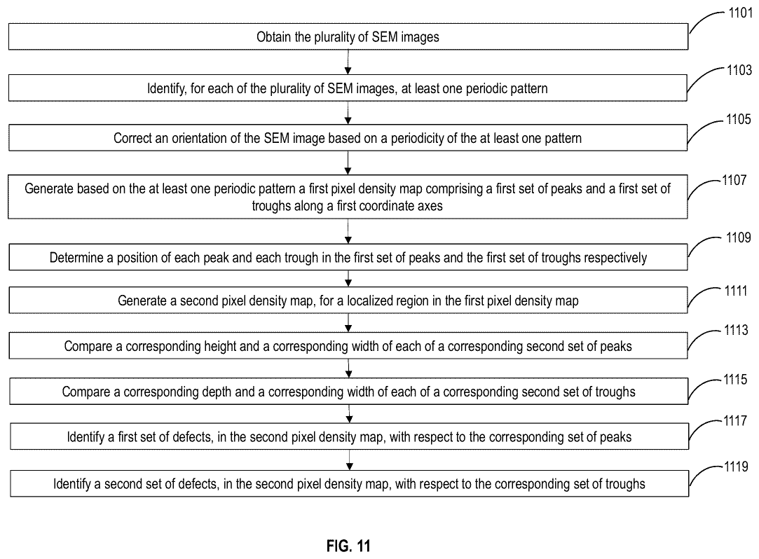

For example, the defect detection operations 411 (as well as each or any combination of the defect detection operations represented by the defect detection operations 411) may represent code, such as a program, a subroutine, a portion of a program, a software component. Additionally, or alternatively, the defect detection operations 411 as well as each or any combination of the defect detection operations represented by the defect detection operations 411) may represent respective hardware (i.e., circuitry or circuitry in combination with code) components configured to perform a corresponding task or operation, such as any one, any combination, or all corresponding tasks or operations of the defect detection operations 501 through 509 of FIG. 5, operations 603 through 619 of FIG. 6, and operations 1101 through 1119 of FIG. 11, respectively described in greater detail further below. The respective hardware components, represented by the defect detection operations 411, may include respective servers that operate independently of each other, and/or some (or all) of the respective hardware components may exist on the same server, or within the same code or program. Each of the respective hardware components, represented by the defect detection operations 411, may include one or more processors, microprocessors, microcomputers, microcontrollers, digital signal processors (DSPs), central processing units (CPUs), application processors (APs), graphic processing units (GPUs), visual processing units (VPUs), AI-dedicated processors such as neural processing units (NPUs), state machines, logic circuitries, and/or any processing circuitries that manipulate signals based on operational instructions. In an example, each of the processor 405, memory 407, database 409, ML model 413, and the respective code and/or hardware components represented by the defect detection operations 411 may be included in the computing device 401 and the computing system 403.

In an embodiment, any of the defect detection operations 411 may be implemented using one or more artificial intelligence (AI) models, which may include a neural network, which as noted above may include a plurality of neural network layers. Examples of such neural networks include but are not limited to, Convolutional Neural Network (CNN), Deep Neural Network (DNN), Recurrent Neural Network (RNN), and Restricted Boltzmann Machine (RBM), may be trained, stored, and executed as described above with respect to the ML model 413, all descriptions of which are also applicable thereto.

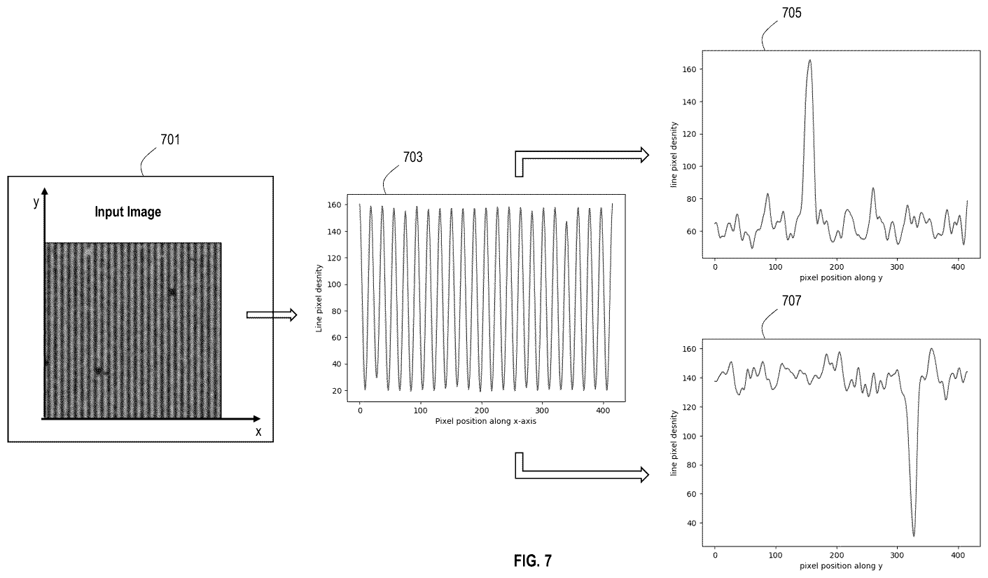

FIG. 5 illustrates example defect detection operations, according to one or more embodiments of the present disclosure. FIG. 6 is a flow diagram of example defect detection operations, according to one or more embodiments of the present disclosure. FIG. 7 illustrates an example defect detection performed using an example SEM image, according to one or more embodiments of the present disclosure.

Referring to FIGS. 5 and 6, example defection operations of the defect detection operations 411 of FIG. 4 may include orientation correction 501, pixel density map generation 503, finding peaks and troughs 505, defect detection 507, and bounding box generation 509 of FIG. 5, and FIG. 6 illustrates an example operational flow of the orientation correction 501, the pixel density map generation 503, the finding of the peaks and troughs 505, the defect detection 507, and the bounding box generation 509. Further, for ease of explanation, the example defect detection of FIG. 7 will be explained with FIGS. 5 and 6 for the sake of brevity and ease of reference. Further, while the reference numerals of FIGS. 4-6 are the same for the like components, and subsequent drawings may be explained with the same reference numbers, this has been done for ease of explanation and understanding and examples are not limited thereto.

Initially, a plurality of SEM images 601 of photolithographic patterns may be obtained, such as described above with respect to FIG. 4. The plurality of SEM images 601 are analyzed by performing various defect detection operations described in the present disclosure (e.g., the defect detection operations 411 of FIG. 4), and potential defects within corresponding photolithographic patterns may be identified.

The orientation correction 501 may include an identification (depicted as operation 603 in FIG. 6) of the at least one periodic pattern within each of the plurality of SEM images 601. A periodic pattern in an SEM image of a photolithographic pattern refers to a recurring arrangement in the pattern depicted that is repeated at regular intervals, often observed as consistent spacing or repeated geometric shapes.

In an embodiment, a periodic pattern in SEM images may be identified by using image processing techniques such as, but not limited to, Fourier transform, wavelet transform, or grayscale gradient descent. In addition, various ML-based techniques such as support vector machines (SVMs) or artificial neural networks (ANNs), which may be trained using large datasets of SEM images with periodic patterns for accurate identification and classification, may be used to classify images based on the periodic pattern. The accurate recognition of periodic patterns in SEM images may lay a foundation for a more accurate identification of defects.

Further, the orientation correction 501 may include a correction (depicted as operation 605 in FIG. 6) of an orientation of each SEM image of the obtained plurality of SEM images 601 based on an analysis of periodicity and directional characteristics of the identified periodic pattern resulting from operation 603. In an embodiment, the orientation may be corrected by rotation, translation, and/or other geometric transformations to align the SEM image with the identified periodic pattern.

In an embodiment, the pixel density map generation 503 may include a generation (depicted as operation 607 in FIG. 6) of a first pixel density map comprising a first set of peaks and a first set of troughs along a first coordinate axis of the first pixel density map, based on the at least one periodic pattern in the corresponding SEM image (e.g., using the orientation corrected image resulting from operation 605). In an embodiment, the first coordinate axis of the first pixel density map corresponds to a direction that may be either parallel or perpendicular to a direction of the at least one periodic pattern in the corresponding SEM image.

For example, an input SEM image is depicted in graph 701 of FIG. 7. After orientation correction by the orientation correction 501, a first pixel density map 703 may be generated (in operation 607) along the illustrated x-axis (first coordinate axis) of the input SEM image 701. In this example of FIG. 7, the illustrated x-axis in graph 701 corresponds to the first coordinate axis of the first pixel density map of operation 607 in FIG. 6.

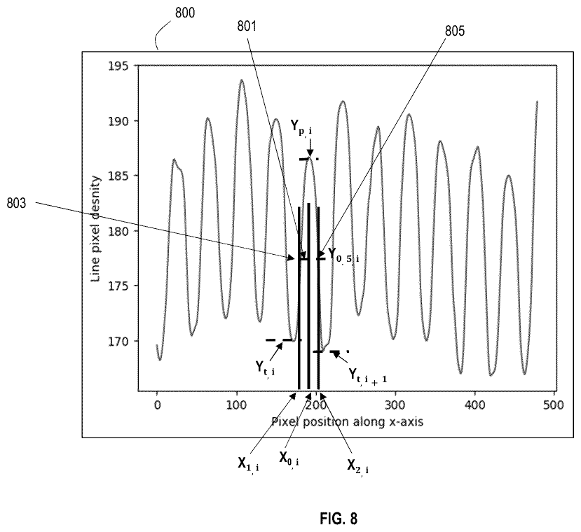

In an embodiment, the finding of the peak and trough 505 may include a determination (depicted as operation 609) of the positions of each peak and each trough in the first pixel density map, as described in greater detail below in conjunction with FIG. 8. Operation 609 may include determinations of the position of each peak and each trough in the first set of peaks and the first set of troughs of the first pixel density map respectively.

Further, the pixel density map generation 503 may include a generation (depicted as operation 611) of a second pixel density map, for a localized region in the first pixel density map, with respect to a corresponding position of each peak and a corresponding position of each trough, such that the second pixel density map includes a second set of peaks and a second set of troughs along the illustrated y-axis (second coordinate axis) of the input SEM image 701.

According to one or more embodiments, a different second pixel density map may be generated for each localized region in the first pixel density map. In an embodiment, each localized region of the first pixel density map may be selected such that the respective localized region is centered around a corresponding peak or a corresponding trough, and bounded by a sampling window of a predefined size, in the first pixel density map. As a non-limiting example, the size of the respective sampling windows may be provided by a user as an input.

The finding of the peak and trough 505 may further include a determination (depicted as operation 613) of the positions of each peak and each trough in the second pixel density map (representing the second set of peaks and the second set of troughs, in the second pixel density map).

With further reference to FIG. 7, graphs 705 and 707 depict, for a localized region in the first pixel density map 703, corresponding portions of the second pixel density map generated along the y-axis of the input SEM image 701. The graph 705 demonstrates a set of peaks of the second pixel density map with respect to the localized region of the first pixel density map 703), and graph 707 demonstrates a set of troughs of the second pixel density map with respect to the localized region of the first pixel density map 703.

In an embodiment, the defect detection 507 may include a comparison (depicted as operation 615), of a corresponding height and a corresponding width of each of a corresponding second set of peaks in the second pixel density map (with respect to the localized region determined from the first pixel density map) with a first height threshold parameter and a first width threshold parameter respectively, and compare a corresponding depth and a corresponding width of each of a corresponding second set of troughs in the second pixel density map (with respect to the localized region determined from the first pixel density map) with a second depth threshold parameter and a second width threshold parameter respectively.

Further, the defect detection 507 may further include an identification (depicted as operation 617) of a first set of defects, as represented in the second pixel density map, with respect to the corresponding set of peaks when at least one of the corresponding heights is determined greater than the first height threshold parameter in operation 615 and the corresponding width is greater than the first width threshold parameter in operation 615.

Furthermore, the defect detection 507 may further include an identification (depicted as operation 619) of a second set of defects, in the second pixel density map, with respect to the corresponding set of troughs when at least one of the corresponding depth is determined lower than the second depth threshold parameter in operation 615 and the corresponding width is greater than the second width threshold parameter in operation 615. An example determination of the positions of each peak and each trough in a pixel density map will be described in greater detail further below in conjunction with FIG. 8.

In an embodiment, the bounding box generation 509 may include a creation of one or more bounding boxes with respect to a corresponding input SEM image to highlight the correspondingly identified first set of defects and the second set of defects for the corresponding input SEM image. The one or more bounding boxes are centered around the x-axis and y-axis positions (in the SEM image) represented by each peak and each trough (of the second pixel density map) corresponding to the identified defect. Further, dimensions of the one or more bounding box may be determined based on the corresponding width of the peak or trough in the second set of defects identified in the second pixel density map.

FIG. 8 illustrates a method of determining positions of peaks and troughs in an example pixel density map 800, according to one or more embodiments of the present disclosure.

According to various embodiments of the present disclosure, firstly, pixel intensity values of each peak and adjacent troughs to the each peak in the pixel density map 800 may be determined along the second coordinate axis (e.g., the illustrated vertical axis) of the pixel density map 800, for each peak in the pixel density map 800. The pixel density map 800 may have been generated along a first axis of an SEM image (e.g., along an x-axis of the SEM image). With the pixel intensity values of each peak and adjacent troughs thereto being determined along the second coordinate axis, the pixel positions of the peaks and troughs may be determined along the first coordinate axis (illustrated horizontal axis) of the pixel density map 800.

In an example embodiment as depicted in FIG. 8, for the i^{th} peak, Y_{t,i} depicts the pixel intensity value of the i^{th} trough, Y_{t,i+1} depicts a pixel intensity value of the (i+1)^{th} trough.

To determine an accurate position of each peak and each trough (e.g., for determining the positions of the periodic patterns in the SEM image), x-coordinates (along the first coordinate axis) of the corresponding peaks and toughs may be determined.

According to an example embodiment of the present disclosure, said x-coordinates may be determined by the following procedure's three operations:

First, a point of half-maximum density value of each peak may be determined by using the pixel intensity values of the each peak and the adjacent troughs, in accordance with Equation 1 below.

$${Y}_{0.5 , i} = 0.5 {Y}_{p , i} + 0.25 ( {Y}_{t , i} + {Y}_{t , i + 1} ) \qquad Equation 1$$

Second, two points on the first coordinate axis are determined where a pixel density profile of the each peak intersects with a line parallel to the first coordinate axis, at the determined (according to Equation 1) point of half-maximum density value. In the present example depicted in FIG. 8, the line 801 parallel to the first coordinate axis intersects the density profile of the i^{th} peak at Y_{0.5,i} at the determined two points 803 and 805. The x-coordinates (on the first coordinate axis) corresponding to the points 803 and 805 are determined as X_{1,i} and X_{2,i}.

Third, the position of each peak is determined using the pixel intensity value of each peak on the second coordinate axis and the determined two points on the first coordinate axis. In the present example, the x-position of the i^{th} peak is determined using Equation 2 below.

$${X}_{0 , i} = 0.5 ( {X}_{1 , i} + {X}_{2 , i} ) \qquad Equation 2$$

While the same operations are not repeated in detail for the sake of brevity, the above-described procedure (and corresponding three operations) may be also be used for determining the position of each trough in the pixel density map. Particularly, to determine the position of each trough in the pixel density map, pixel intensity values of the each trough and adjacent peaks to each trough may be determined along the second coordinate axis. Further, a point of half-maximum density value of each trough is determined by using the pixel intensity values of each trough and the adjacent peaks. Furthermore, two points on the first coordinate axis may be determined where a density profile of the each trough intersects with a line parallel to the first coordinate axis, at the point of half-maximum density value. Moreover, the position of each trough is determined using the pixel intensity value of the each trough on the second coordinate axis and the determined two points on the first coordinate axis.

The above-described procedure according to one or more embodiments of the present disclosure procedure may help to eliminate false peaks and help enable the determination of an accurate peak and trough positions. In an additional or alternate embodiment, the same above-described procedure may be followed for determining positions of periodic patterns when periodicity in the pattern of the SEM image is along the y-axis in the SEM image. In such a case, the first coordinate axis and the second coordinate axis of the above procedure would correspond to the y-axis and the x-axis, respectively.

Once the positions of the periodic patterns are determined, defects may be identified by detecting anomalies represented in the second pixel density map along the pattern, by constructing the second pixel density map in a localized narrow region of width w centered around a corresponding peak/trough position in the first pixel density map. In an embodiment, the width w may be determined using the difference between the two points on the first coordinate axis. For example, in pixel density map 800, the width w of a localized narrow region centered around the i^{th} peak can be determined by (X_{2,i}−X_{1,i}).

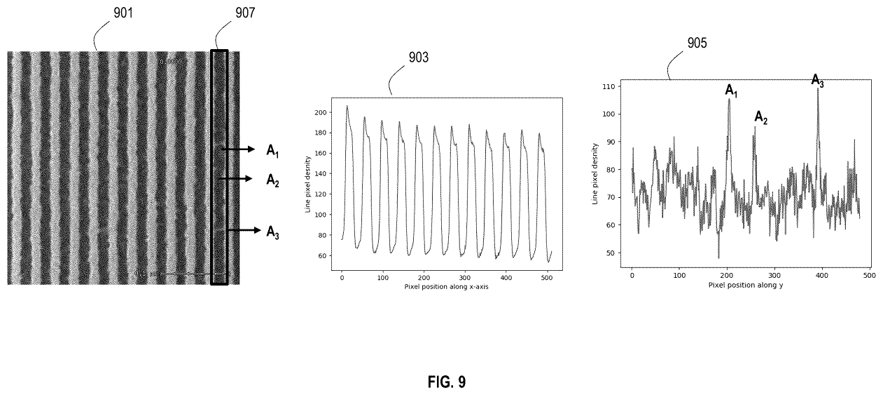

FIG. 9 illustrates an example defect detection using an example second pixel density map, according to one or more embodiments of the present disclosure.

In FIG. 9, an input SEM image 901 shows a photolithographic pattern with potential defects marked as A₁, A₂, and A₃. Since the periodic pattern in the SEM image 901 is along the x-axis (illustrated horizontal axis) of the SEM image 901, a first pixel density map 903, is generated along x-coordinates of the x-axis of the SEM image 901.

Further, a second pixel density map 905 for a localized region 907 of the SEM image 901 (e.g., determined using the first pixel density map 903), of width w, may be generated according to one or more embodiments of the present disclosure. The anomalies (which are potential defects) A₁, A₂, and A₃ may be detected in the second pixel density map 905. The detected anomalies may be detected as defects if their corresponding peak intensities (i.e., the vertical axis' ‘line pixel density’ of corresponding peaks of the second pixel density map 905) and corresponding peak widths (measurable using the horizontal axis of the second pixel density map 905) are greater than predetermined threshold values.

In an embodiment, a corresponding height (i.e., based on the vertical axis of the second pixel density map 905) and a corresponding width (based on the horizonal axis of the second pixel density map 905) of each of a corresponding second set of peaks (in the second pixel density map 905, corresponding to the localized region 907 determined using the first pixel density map 905) are compared with a first height threshold parameter and a first width threshold parameter respectively. Further, the corresponding depth (i.e., based on the vertical axis of the second pixel density map 905) and a corresponding width (based on the horizonal axis of the second pixel density map 905) of each of a corresponding second set of troughs (in the second pixel density map 905, corresponding to the localized region 907 determined using the first pixel density map 905) are compared with a second depth threshold parameter and a second width threshold parameter respectively.

Based on such comparisons, a first set of defects may be identified in the second pixel density map 905 with respect to the corresponding second set of peaks when at least one of the corresponding heights is greater than the first height threshold parameter and a corresponding peak width is greater than the first width threshold parameter, and/or a second set of defects may be identified in the second pixel density map 905, with respect to the corresponding second set of troughs when at least one of the corresponding depths is lower than the second depth threshold parameter and a corresponding trough width is greater than the second width threshold parameter.

Accordingly, based on such comparisons, anomalies A₁, A₂, and A₃ may be identified as defects (e.g., anomalies A₁, A₂, and A₃ may be detected as ‘bridge’ defects, as adjacent features in the circuit pattern that were not intended to be electrically connected), depicted by peaks in the second pixel density map 905 when at least one of the corresponding heights is greater than the first height threshold parameter and a corresponding peak width is greater than the first width threshold parameter.

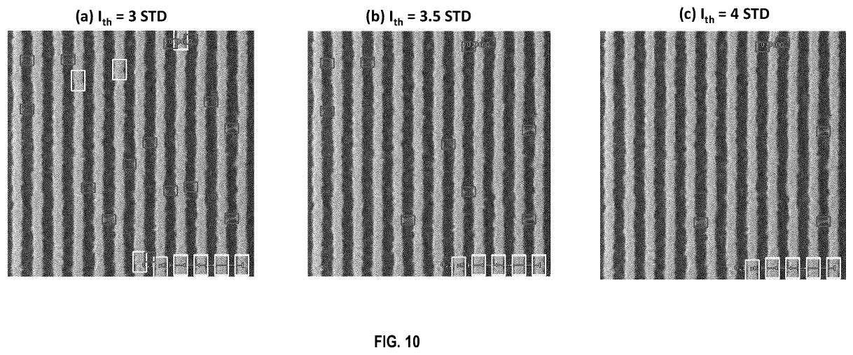

However, while anomalies A₁ and A₃ may be correctly identified as bridge defects, anomaly A₂ may not be a bridge defect, but rather, may be what is termed a scum (or scum haze) false defect (e.g., a thin, unwanted residue of photoresist material left behind on the substrate after the development process, as a film of partially exposed resist that remains in areas where it should have been completely removed, which could potentially later cause defects in a subsequent final pattern by future bridging of features or affecting subsequent etching operations). This potential defect detection issue is further described below in conjunction with FIG. 10.

FIG. 10 illustrates example sensitivities of defect detection with different threshold values, according to one or more embodiments of the present disclosure.

As depicted in FIG. 10, the number of defects detected in a same SEM image decreases when the settings for the detection threshold values are increased as can be seen in illustrations (a) through (c). For example, keeping the threshold too small (e.g., in illustration (a) where the threshold was optimized according to 3 standard deviations (STD), such as with respect to heights and widths of peaks and/or depths and widths of troughs in a second pixel density map) may lead to the detection of false defects such as scum, while keeping the threshold too high (e.g., in illustration (c) where the threshold was 4 STD) may result in the skipping or missing of actual defects. However, keeping the threshold optimized or optimal (e.g., in illustration (b) where the threshold was 3.5 STD) may result in the accurate detection of defects. Therefore, further descriptions below explain how to determine such optimized threshold values for accurate defect detection so that false positives and false negatives are reduced or eliminated.

According to one or more embodiments of the present disclosure, the first height threshold parameter, the first width threshold parameter, the second depth threshold parameter, and the second width threshold parameter may be determined by optimizing one or more initial threshold parameters associated with the standard deviation of the corresponding height and the corresponding width of the corresponding peak, and the corresponding depth and the corresponding width of the corresponding trough in the second set of peaks and the second set of troughs (respectively of the aforementioned second pixel density maps) using a machine learning (ML) model. As noted above, the first height threshold parameter and the first width threshold parameter may be used to identify the first set of defects with respect to peaks in a second pixel density map, and the second depth threshold parameter and the second width threshold parameter may be used to identify the second set of defects with respect to troughs in the second pixel density map.

For example, the first height threshold parameter, the first width threshold parameter, the second depth threshold parameter, and the second width threshold (commonly referred to as the threshold values) may be optimized using the ML model 413 of FIG. 4.

To optimize the threshold values, initially, a subset of the plurality of SEM images may be obtained and a set of defects (e.g., referred to as a third set of defects) in the obtained subset of the plurality of SEM images may be detected based on one or more initial threshold parameters as described herein with respect to any operations of FIGS. 4-9 and 11-12. The initial threshold parameter-based detected defects may then be compared (e.g., for at least one of one or more incorrect defects or one or more missed defects in the third set of defects) to predetermined defects (e.g., as previously user or otherwise labeled defects) of the corresponding SEM images and/or a user may compare (e.g., for at least one of one or more incorrect defects or one or more missed defects in the third set of defects) the detected defects with the corresponding SEM images, and results of either or both of these comparisons may be used by the ML model 413 to generate optimized threshold values (e.g., an optimized first height threshold parameter, an optimized first width threshold parameter, an optimized second depth threshold parameter, and/or an optimized second width threshold parameter).

In an additional or alternative example, the one or more initial threshold parameters may be optimized (e.g., adjustments thereto determined) based on a calculation of noise, pixel intensity, standard deviation values, and line edge roughness values in an SEM image.

According to one or more embodiments of the present disclosure, the one or more initial threshold parameters may be optimized for every new batch of SEM images when process parameters or imaging procedure changes.

FIG. 11 illustrates a method for detecting one or more defects in a plurality of SEM images of photolithographic patterns, according to one or more embodiments of the present disclosure. The method includes a series of operations 1101 through 1119 executed by one or more processors of a computing system. As a non-limiting example, and for explanation purposes, the operations will be described as being performed by the processor 405 of the computing system 403 of FIG. 4.

In operation 1101, the processor 405 may obtain the plurality of SEM images 601.

In operation 1103, the processor 405 may identify, for each of the plurality of SEM images, at least one periodic pattern.

In operation 1105, the processor 405 may correct an orientation of at least one of the SEM images based on a respective periodicity of the at least one pattern of the corresponding SEM image.

In operation 1107, the processor 405 may generate, based on the at least one periodic pattern, of the corresponding SEM image, a first pixel density map comprising a first set of peaks and a first set of troughs along a first coordinate axis of the first pixel density map. The first pixel density map may be generated from the orientation corrected SEM image resulting from operation 1105. In an embodiment, the first coordinate axis may correspond to a direction either parallel or perpendicular to a direction of the at least one periodic pattern in the corresponding SEM image.

In operation 1109, the processor 405 may determine a position of each peak and each trough in the first set of peaks and the first set of troughs respectively.

In an embodiment, to determine the position of the each peak the processor 405 may determine, for the each peak in the first pixel density map, pixel intensity values of the each peak and adjacent troughs to the each peak along a second coordinate axis of the first pixel density map. For example, the first coordinate axis of the first pixel density map may represent pixel positions along an x-axis of the corresponding SEM image, and the second coordinate axis of the first pixel density map may represent line pixel density intensities. Thereafter, the processor 405 determines a point of half-maximum density value of the each peak by using the pixel intensity values of the each peak and the adjacent troughs.

Thereafter, for each peak, the processor 405 may determine two points on the first coordinate axis of the first pixel density map for a corresponding peak where a pixel density profile of the corresponding peak intersects with a line parallel to the first coordinate axis of the first pixel density map, at the point of half-maximum density value. Finally, for each peak, the processor 405 may determine the position of the corresponding peak using the pixel intensity value of the corresponding peak on the second coordinate axis of the first pixel density map and the determined two points for the corresponding peak on the first coordinate axis of the first pixel density map. In an embodiment, for each peak, a width of a corresponding localized region corresponds to a difference between the two points for the corresponding peak on the first coordinate axis of the first pixel density map.

In an embodiment, to determine the position of the each trough, the processor 405 may determine, for the each trough in the first pixel density map, pixel intensity values of the each trough and adjacent peaks to the each trough along the second coordinate axis of the first pixel density map. Further, the processor 405 determines a point of half-maximum density value of the each trough by using the pixel intensity values of the each trough and the adjacent peaks. Furthermore, for each trough, the processor 405 may determine two points on the first coordinate axis of the first pixel density map for a corresponding trough where a density profile of the corresponding trough intersects with a line parallel to the first coordinate axis of the first pixel density map, at the point of half-maximum density value. Finally, for each trough, the processor 405 may determine the position of the corresponding trough using the pixel intensity value of the corresponding trough on the second coordinate axis of the first pixel density map and the determined two points for the corresponding trough on the first coordinate axis of the first pixel density map.

In operation 1111, the processor 405 may generate a second pixel density map, for a localized region in the first pixel density map, with respect to a corresponding position of each peak and a corresponding position of each trough in the first pixel density map, such that each second pixel density map (e.g., one for each localized region) comprises a second set of peaks and a second set of troughs along a second coordinate axis thereof.

In operation 1113, using one of the generated second pixel density maps as an example, the processor 405 compares a corresponding height and a corresponding width of each of a corresponding second set of peaks in the example one second pixel density map with a first height threshold parameter and a first width threshold parameter respectively.

In operation 1115, the processor 405 compares a corresponding depth and a corresponding width of each of a corresponding second set of troughs in the example one second pixel density map with a second depth threshold parameter and a second width threshold parameter respectively.

In an embodiment, the processor 405 determines the first height threshold parameter, the first width threshold parameter, the second depth threshold parameter, and the second width threshold parameter by optimizing one or more initial threshold parameters associated with standard deviation of the corresponding height and the corresponding width of the corresponding peak in the example one second pixel density map, and the corresponding depth and the corresponding width of the corresponding trough in the second set of peaks and the second set of troughs in the example one second pixel density map using the ML model 413.

In an embodiment, to optimize the one or more initial threshold parameters, the processor 405 may obtain a subset of the plurality of SEM images. Further, the processor 405 may detect a set of defects (referred to as a third set of defects) in the obtained subset of the plurality of SEM images based on the one or more initial threshold parameters. Moreover, the processor 405 optimizes, using the ML model 413, the one or more initial threshold parameters. For example, a user feedback that may include at least one of one or more incorrect defects or one or more missed defects in the third set of defects, as non-limiting example, may be provided to the ML model 413 along with the initial threshold parameters, and the ML model 413 may generate optimized versions of the one or more threshold parameters.

In operation 1117, the processor 405 may identify a first set of defects, in the second pixel density map, with respect to the corresponding set of peaks when at least one of the corresponding height of a corresponding peak is greater than the first height threshold parameter and a corresponding width of the corresponding peak is greater than the first width threshold parameter.

In operation 1119, the processor 405 may identify a second set of defects, in the second pixel density map, with respect to the corresponding set of troughs when at least one of the corresponding depths of a corresponding trough is lower than the second depth threshold parameter and a corresponding width of the corresponding trough is greater than the second width threshold parameter.

Operations 1113 through 1119 may be performed for each second pixel density map generated in operation 1111.

Operation 1103 may include detecting hole and pillar patterns in one or more SEM images, and operations 110 through 1119 may be performed to detecting defects in such hole and pillar patterns in one or more of the SEM images.

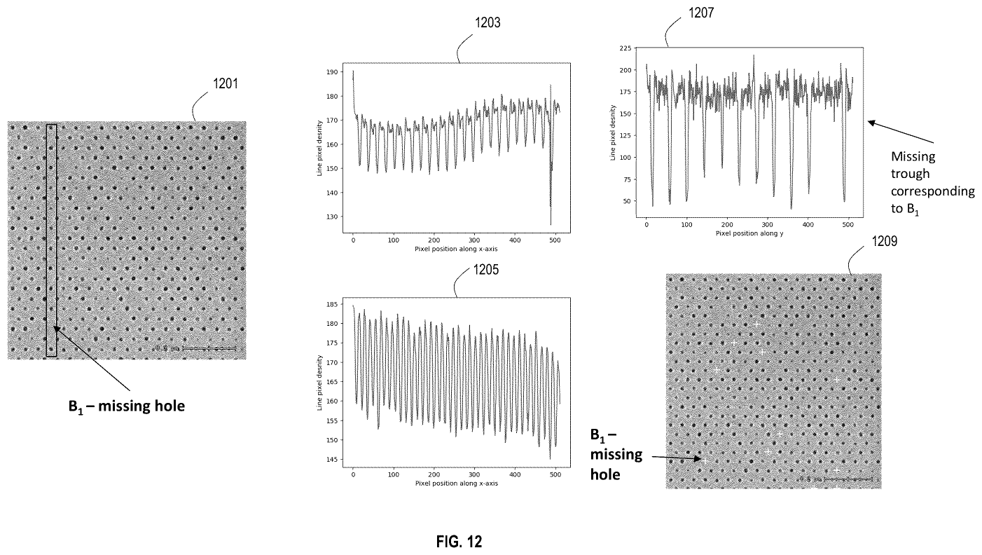

FIG. 12 illustrates an example defect detection in an example SEM image of a hole photolithographic pattern, according to one or more embodiments of the present disclosure. As shown in FIG. 12, defect detection is performed on an input SEM image 1201 corresponding to a hole photolithographic pattern, where an area marked as B₁ depicts one missing hole.

According to one or more embodiments of the present disclosure, first pixel density maps 1203 and 1205 may be respectively generated along the x-axis and y-axis of the SEM image 1201 since the hole pattern is periodic along both directions. Further, a second pixel density map 1207 may be generated along the y-axis of the SEM image 1201 for a localized region determined from the first pixel density map 1203, which for illustrative purposes is marked with a rectangular block in the SEM image 1201. Finally, one or more defects may be detected (based on aforementioned threshold comparisons with respect to the second density map 1207) and marked (as illustrated crosses overlaying the SEM image 1201) in the output SEM image 1209. Though not illustrated in FIG. 12, another second pixel density map may be generated along the x-axis of the SEM image 1201 for another localized region determined from the first pixel density map 1205, and one or more defects may be detected using the other second pixel density map and then also marked in the output SEM image 1209.

One or more embodiments may provide techniques, for detecting one or more defects in a plurality of SEM images of photolithographic patterns, that may enable detection of ever smaller or even the smallest defects in the photolithographic patterns that are often missed using previous AI-based defect detection approaches. Through defect detection techniques of one or more embodiments described herein, such smaller or smallest defects may also be detected with high accuracies, detecting defects which are not detected by typical defect detection techniques.

One or more embodiments may provide techniques, for detecting one or more defects in a plurality of SEM images of photolithographic patterns, that may not require training data for model training and development, as would typically be required in typical ML-based detection techniques.

Further, while examples have been explained using SEM images, and through SEM imaging-based defect detection, examples are not limited thereto as such explanations are applicable to not just SEM imaging-based defect detection, but may also be more widely applicable to other defect detection techniques used in semiconductor fabrication such as optical imaging techniques in alternate embodiments.

Further, while examples have been explained with respect to the detection of defects in line, hole, and/or pillar patterns, examples are not limit to the same, as such explanations are also applicable to other pattern characteristics in addition to, or other than, line, hole, and pillar patterns, such as for overlay detection, as a non-limiting example.

The processors, memories, databases, communication interfaces, sensors, and execution or performance of AI models and defect detection operations described herein, including descriptions with respect to respect to FIGS. 1-12, are implemented by or representative of hardware components. As described above, or in addition to the descriptions above, examples of hardware components that may be used to perform the operations described in this application where appropriate include controllers, sensors, generators, drivers, memories, comparators, arithmetic logic units, adders, subtractors, multipliers, dividers, integrators, and any other electronic components configured to perform the operations described in this application. In other examples, one or more of the hardware components that perform the operations described in this application are implemented by computing hardware, for example, by one or more processors or computers. A processor or computer may be implemented by one or more processing elements, such as an array of logic gates, a controller and an arithmetic logic unit, a digital signal processor, a microcomputer, a programmable logic controller, a field-programmable gate array, a programmable logic array, a microprocessor, or any other device or combination of devices that is configured to respond to and execute instructions in a defined manner to achieve a desired result. In one example, a processor or computer includes, or is connected to, one or more memories storing instructions or software that are executed by the processor or computer. Hardware components implemented by a processor or computer may execute instructions or software, such as an operating system (OS) and one or more software applications that run on the OS, to perform the operations described in this application. The hardware components may also access, manipulate, process, create, and store data in response to execution of the instructions or software. For simplicity, the singular term “processor” or “computer” may be used in the description of the examples described in this application, but in other examples multiple processors or computers may be used, or a processor or computer may include multiple processing elements, or multiple types of processing elements, or both, and thus while some references may be made to a singular processor or computer, such references also are intended to refer to multiple processors or computers. For example, a single hardware component or two or more hardware components may be implemented by a single processor, or two or more processors, or a processor and a controller. One or more hardware components may be implemented by one or more processors, or a processor and a controller, and one or more other hardware components may be implemented by one or more other processors, or another processor and another controller. One or more processors, or a processor and a controller, may implement a single hardware component, or two or more hardware components. As described above, or in addition to the descriptions above, example hardware components may have any one or more of different processing configurations, examples of which include a single processor, independent processors, parallel processors, single-instruction single-data (SISD) multiprocessing, single-instruction multiple-data (SIMD) multiprocessing, multiple-instruction single-data (MISD) multiprocessing, and multiple-instruction multiple-data (MIMD) multiprocessing.

The methods illustrated in, and discussed with respect to, FIGS. 1-12 that perform the operations described in this application are performed by computing hardware, for example, by one or more processors or computers, implemented as described above implementing instructions (e.g., computer or processor/processing device readable instructions) or software to perform the operations described in this application that are performed by the methods. For example, a single operation or two or more operations may be performed by a single processor, or two or more processors, or a processor and a controller. One or more operations may be performed by one or more processors, or a processor and a controller, and one or more other operations may be performed by one or more other processors, or another processor and another controller. One or more processors, or a processor and a controller, may perform a single operation, or two or more operations. References to a processor, or one or more processors, as a non-limiting example, configured to perform two or more operations refers to a processor or two or more processors being configured to collectively perform all of the two or more operations, as well as a configuration with the two or more processors respectively performing any corresponding one of the two or more operations (e.g., with a respective one or more processors being configured to perform each of the two or more operations, or any respective combination of one or more processors being configured to perform any respective combination of the two or more operations). Likewise, a reference to a processor-implemented method is a reference to a method that is performed by one or more processors or other processing or computing hardware of a device or system.

Instructions or software to control computing hardware, for example, one or more processors or computers, to implement the hardware components and perform the methods as described above may be written as computer programs, code segments, instructions or any combination thereof, for individually or collectively instructing or configuring the one or more processors or computers to operate as a machine or special-purpose computer to perform the operations that are performed by the hardware components and the methods as described above. In one example, the instructions or software include machine code that is directly executed by the one or more processors or computers, such as machine code produced by a compiler. In another example, the instructions or software includes higher-level code that is executed by the one or more processors or computer using an interpreter. The instructions or software may be written using any programming language based on the block diagrams and the flow charts illustrated in the drawings and the corresponding descriptions herein, which disclose algorithms for performing the operations that are performed by the hardware components and the methods as described above.

The instructions or software to control computing hardware, for example, one or more processors or computers, to implement the hardware components and perform the methods as described above, and any associated data, data files, and data structures, may be recorded, stored, or fixed in or on one or more non-transitory computer-readable storage media, and thus, not a signal per se. As described above, or in addition to the descriptions above, examples of a non-transitory computer-readable storage medium include one or more of any of read-only memory (ROM), random-access programmable read only memory (PROM), electrically erasable programmable read-only memory (EEPROM), random-access memory (RAM), dynamic random access memory (DRAM), static random access memory (SRAM), flash memory, non-volatile memory, CD-ROMs, CD-Rs, CD+Rs, CD-RWs, CD+RWs, DVD-ROMs, DVD-Rs, DVD+Rs, DVD-RWs, DVD+RWs, DVD-RAMs, BD-ROMs, BD-Rs, BD-R LTHs, BD-REs, blue-ray or optical disk storage, hard disk drive (HDD), solid state drive (SSD), flash memory, a card type memory such as multimedia card micro or a card (for example, secure digital (SD) or extreme digital (XD)), magnetic tapes, floppy disks, magneto-optical data storage devices, optical data storage devices, hard disks, solid-state disks, and/or any other device that is configured to store the instructions or software and any associated data, data files, and data structures in a non-transitory manner and provide the instructions or software and any associated data, data files, and data structures to one or more processors or computers so that the one or more processors or computers can execute the instructions. In one example, the instructions or software and any associated data, data files, and data structures are distributed over network-coupled computer systems so that the instructions and software and any associated data, data files, and data structures are stored, accessed, and executed in a distributed fashion by the one or more processors or computers.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents.

Therefore, in addition to the above and all drawing disclosures, the scope of the disclosure is also inclusive of the claims and their equivalents, i.e., all variations within the scope of the claims and their equivalents are to be construed as being included in the disclosure.

What is claimed is:

1. A processor-implemented method, the method comprising:
generating a first pixel density map comprising a first set of peaks and a first set of troughs respectively along a first direction in a scanning electron microscope (SEM) image corresponding to a periodic pattern in the SEM image, where the first set of peaks are respective peaks in pixel density intensity in the first pixel density map and the first set of troughs are respective troughs in the pixel density intensity in first pixel density map;
generating a second pixel density map, for a localized region determined in the first pixel density map dependent on a determined position of a peak in the first set of peaks and a determined position of a trough in the first set of troughs, where the second pixel density map comprises a second set of peaks and/or a second set of troughs along a second direction of the SEM image that is perpendicular to the first direction, and where the second set of peaks are respective peaks in pixel density intensity in the second pixel density map and the second set of troughs are respective troughs in the pixel density intensity in the second pixel density map;
detecting one or more first defects in the SEM image by comparing, for each of the second set of peaks, a corresponding height and width of a corresponding peak of the second set of peaks with a first height threshold parameter and a first width threshold parameter, respectively, when the second pixel density map comprises the second set of peaks; and
detecting one or more second defects in the SEM image by comparing, for each of the second set of troughs, a corresponding depth and width of a corresponding trough of the second set of troughs with a second depth threshold parameter and a second width threshold parameter, respectively, when the second pixel density map comprises the second set of troughs.

2. The method of claim 1,
wherein the detecting of the one or more first defects further comprises identifying a first set of defects, in the second pixel density map, with respect to the second set of peaks when at least one of the corresponding heights and widths of the corresponding peaks is a height and width that are respectively greater than the first height threshold parameter and the first width threshold parameter, and
wherein the detecting of the one or more second defects further comprises identifying a second set of defects, in the second pixel density map, with respect to the second set of troughs when at least one of the corresponding depths and widths of the corresponding troughs is a depth and width that are lower than the second depth threshold parameter and greater than the second width threshold parameter, respectively.

3. The method of claim 1, further comprising identifying, for each of a plurality of SEM images that include the SEM image, at least one periodic pattern that includes the periodic pattern.

4. The method of claim 3, wherein the first direction corresponds to a direction either parallel or perpendicular to a direction of the at least one periodic pattern in the SEM image.

5. The method of claim 3, further comprising correcting an orientation of the SEM image based on a periodicity of the periodic pattern,
wherein, in the generating of the first pixel density map, the first set of peaks and the first set of troughs are respectively generated along a first coordinate axis of the SEM image with corrected orientation.

6. The method of claim 1, further comprising, for each peak in the first set of peaks:
determining, along a second coordinate axis of the first pixel density map, a first pixel intensity value of a corresponding peak of the first set of peaks and first pixel intensity values of adjacent troughs, of the first set of troughs, to the corresponding peak;
determining a point of half-maximum density value of the corresponding peak by using the first pixel intensity value of the corresponding peak and the first pixel intensity values of the adjacent troughs to the corresponding peak of the first set of peaks;
determining two points for the corresponding peak of the first set of peaks on a first coordinate axis of the first pixel density map where a pixel density profile of the corresponding peak of the first set of peaks intersects with a line parallel to the first coordinate axis at the point of half-maximum density value of the corresponding peak of the first set of peaks; and
determining a position of the corresponding peak of the first set of peaks using the first pixel intensity value of the corresponding peak of the first set of peaks and the determined two points for the corresponding peak of the first set of peaks.

7. The method of claim 6, wherein a width of the localized region corresponds to a difference between the determined two points for the corresponding peak in the first set of peaks.

8. The method of claim 1, further comprising, for each trough in the first set of troughs:
determining, along a second coordinate axis of the first pixel density map, a first pixel intensity value of a corresponding trough of the first set of troughs and first pixel intensity values of adjacent peaks to the corresponding trough of the first set of troughs;
determining a point of half-maximum density value of the corresponding trough of the first set of troughs by using the first pixel intensity value of the corresponding trough of the first set of troughs and the first pixel intensity values of the adjacent peaks to the corresponding trough of the first set of troughs;
determining two points for the corresponding trough of the first set of troughs on a first coordinate axis of the first pixel density map where a density profile of the corresponding trough of the first set of troughs intersects with a line parallel to the first coordinate axis, at the point of half-maximum density value of the corresponding trough of the first set of troughs; and
determining a position of the corresponding trough of the first set of troughs using the first pixel intensity value of the corresponding trough of the first set of troughs and the determined two points for the corresponding trough of the first set of troughs.

9. The method of claim 1, further comprising:
determining the first height threshold parameter, the first width threshold parameter, the second depth threshold parameter, and the second width threshold parameter by optimizing, using a machine learning (ML) model, one or more initial threshold parameters associated with standard deviations of the corresponding heights and the corresponding widths of the corresponding peaks of the second set of peaks, and the corresponding depths and the corresponding widths of the corresponding troughs of the second set of troughs.

10. The method of claim 9, wherein the optimizing comprises:
obtaining a subset of a plurality of SEM images that include the SEM image;
detecting a set of defects in the obtained subset of the plurality of SEM images based on the one or more initial threshold parameters; and
optimizing, using the ML model, the one or more initial threshold parameters based on user feedback comprising one or more incorrect defects in the set of defects and/or one or more missed defects in the set of defects.

11. A computing system, the computing system comprises:
one or more processors; and
a memory storing code, which when executed by the one or more processors configures the one or more processors to:
generate a first pixel density map comprising a first set of peaks and a first set of troughs respectively along a first direction in a scanning electron microscope (SEM) image corresponding to a periodic pattern in the SEM image, where the first set of peaks are respective peaks in pixel density intensity in the first pixel density map and the first set of troughs are respective troughs in the pixel density intensity in first pixel density map;
generate a second pixel density map, for a localized region determined in the first pixel density map dependent on a determined position of a peak in the first set of peaks and a determined position of a trough in the first set of troughs, where the second pixel density map comprises a second set of peaks and/or a second set of troughs along a second direction of the SEM image that is perpendicular to the first direction, and where the second set of peaks are respective peaks in pixel density intensity in the second pixel density map and the second set of troughs are respective troughs in the pixel density intensity in the second pixel density map;
detect one or more first defects in the SEM image by comparing, for each of the second set of peaks, a corresponding height and width of a corresponding peak of the second set of peaks with a first height threshold parameter and a first width threshold parameter, respectively, when the second pixel density map comprises the second set of peaks; and
detect one or more second defects in the SEM image by comparing, for each of the second set of troughs, a corresponding depth and width of a corresponding trough of the second set of troughs with a second depth threshold parameter and a second width threshold parameter, respectively, when the second pixel density map comprises the second set of troughs.

12. The computing system of claim 11,
wherein, for the detecting of the one or more first defects, the code configures the one or more processors to identify a first set of defects, in the second pixel density map, with respect to the second set of peaks when at least one of the corresponding heights and widths of the corresponding peaks is a height and width that are respectively greater than the first height threshold parameter and the first width threshold parameter, and
wherein, for the detecting of the one or more second defects, the code configures the one or more processors to identify a second set of defects, in the second pixel density map, with respect to the second set of troughs when at least one of the corresponding depths and widths of the corresponding troughs is a depth and width that are lower than the second depth threshold parameter and greater than the second width threshold parameter, respectively.

13. The computing system of claim 11, wherein the code further configures the one or more processors to identify, for each of a plurality of SEM images that include the SEM image, at least one periodic pattern that includes the periodic pattern.

14. The computing system of claim 13, wherein the first direction corresponds to a direction either parallel or perpendicular to the at least one periodic pattern in the SEM image.

15. The computing system of claim 13,
wherein the code further configures the one or more processors to correct an orientation of the SEM image based on a periodicity of the periodic pattern, and
wherein, in the generating of the first pixel density map, the first set of peaks and the first set of troughs are respectively generated along a first coordinate axis of the SEM image with corrected orientation.

16. The computing system of claim 11, wherein the code further configures the one or more processors to, for each peak in the first set of peaks:
determine, along a second coordinate axis of the first pixel density map, a first pixel intensity value of a corresponding peak of the first set of peaks and first pixel intensity values of adjacent troughs, of the first set of troughs, to the corresponding peak;
determine a point of half-maximum density value of the corresponding peak by using the first pixel intensity value of the corresponding peak and the first pixel intensity values of the adjacent troughs to the corresponding peak of the first set of peaks;
determine two points for the corresponding peak of the first set of peaks on a first coordinate axis of the first pixel density map where a pixel density profile of the corresponding peak of the first set of peaks intersects with a line parallel to the first coordinate axis at the point of half-maximum density value of the corresponding peak of the first set of peaks; and
determine a position of the corresponding peak of the first set of peaks using the first pixel intensity value of the corresponding peak of the first set of peaks and the determined two points for the corresponding peak of the first set of peaks.

17. The computing system of claim 16, wherein a width of the localized region corresponds to a difference between the determined two points for the corresponding peak in the first set of peaks.

18. The computing of claim 11, wherein the code further configures the one or more processors to, for each trough in the first set of troughs:
determine, along a second coordinate axis of the first pixel density map, a first pixel intensity value of a corresponding trough of the first set of troughs and first pixel intensity values of adjacent peaks to the corresponding trough of the first set of troughs;
determine a point of half-maximum density value of the corresponding trough of the first set of troughs by using the first pixel intensity value of the corresponding trough of the first set of troughs and the first pixel intensity values of the adjacent peaks to the corresponding trough of the first set of troughs;
determine two points for the corresponding trough of the first set of troughs on a first coordinate axis of the first pixel density map where a density profile of the corresponding trough of the first set of troughs intersects with a line parallel to the first coordinate axis, at the point of half-maximum density value of the corresponding trough of the first set of troughs; and
determine a position of the corresponding trough of the first set of troughs using the first pixel intensity value of the corresponding trough of the first set of troughs and the determined two points for the corresponding trough of the first set of troughs.

19. The computing system of claim 11, wherein the code further configures the one or more processors to:
determine the first height threshold parameter, the first width threshold parameter, the second depth threshold parameter, and the second width threshold parameter by optimizing, using a machine learning (ML) model, one or more initial threshold parameters associated with standard deviations of the corresponding heights and the corresponding widths of the corresponding peaks of the second set of peaks, and the corresponding depths and the corresponding widths of the corresponding troughs of the second set of troughs.

20. The computing system of claim 19, wherein, for the optimizing of the one or more initial threshold parameters, the code configures the one or more processors to:
obtain a subset of a plurality of SEM images that include the SEM image;
detect a set of defects in the obtained subset of the plurality of SEM images based on the one or more initial threshold parameters; and
optimize, using the ML model, the one or more initial threshold parameters based on user feedback comprising one or more incorrect defects in the set of defects and/or one or more missed defects in the set of defects.
